(19) United States
(12) Patent Application Publication
(10) Pub. No.: US 2010/0308923 A1
(43) Pub. Date: Dec. 9, 2010

(54) MAGNETIC VOLTAGE CONTROLLED OSCILLATOR

(75) Inventor: Shehzaad Kaka, Pittsburgh, PA (US)

Correspondence Address: SEAGATE TECHNOLOGY LLC;C/O WESTMAN, CHAMPLIN & KELLY, P.A., SUITE 1400, 900 SECOND AVENUE SOUTH, MINNEAPOLIS, MN, 55402-3244, US

(73) Assignee: SEAGATE TECHNOLOGY LLC, Scotts Valley, CA (US)

(21) Appl. No.: 12/478,417

(22) Filed: Jun. 4, 2009

(51) Int. Cl. H03K 3/03

(52) U.S. Cl. 331/46

(57) ABSTRACT

The disclosure is related to oscillators and more specifically voltage controlled oscillators. Magnetic voltage controlled oscillators are presented that comprise current-biased magnetic thin film structures that can exhibit microwave oscillations and are tunable with current as well as magnetic field. In a particular embodiment, an array of oscillators, which may be activated with a current while in a magnetic field, can be positioned adjacent a spin valve layer to produce a spinwave disturbance in the spin valve layer. An array of detectors that can sense periodic motion of the magnetization of the spin valve layer may also be positioned adjacent the spin valve layer. The detectors may produce an oscillating output signal from the detected periodic motion.

### FIELD OF THE DISCLOSURE

The present disclosure is generally related to oscillators. Further, the present disclosure is related to voltage controlled oscillators.

### BRIEF DESCRIPTION OF THE DRAWINGS

FIG. 1 is a diagram of an illustrative embodiment of a system including an oscillating device;

FIG. 2 is a diagram of an illustrative embodiment of an oscillating device;

FIG. 3 is a diagram of another illustrative embodiment of an oscillating device;

FIG. 4 is a diagram of an illustrative embodiment of a system including an oscillating device and a detector;

FIG. 5 is a diagram of another illustrative embodiment of a system including an oscillating device and a detector;

FIG. 6 is a diagram of another illustrative embodiment of a system including an oscillating device and a detector; and

FIG. 7 is a diagram of another illustrative embodiment of a system including an oscillating device and a detector.

### DETAILED DESCRIPTION

In the following detailed description of the embodiments, reference is made to the accompanying drawings which form a part hereof, and in which are shown by way of illustration of specific embodiments. It is to be understood that other embodiments may be utilized and structural changes may be made without departing from the scope of the present disclosure.

Gigahertz frequency oscillator circuits can be key components of wireless transceiver technology, such as cellular telephone handsets, wireless networks, and local proximity wireless devices such as Bluetooth enabled devices. As these devices continue to be designed smaller and with more features, an oscillator having a relatively small footprint can be useful. Thus, presented herein are designs of oscillators comprising mutually phase-locked oscillating elements with each having a relatively small footprint, such as 50×50 nm².

The oscillator may comprise magnetic thin film structures. Specifically, current-biased magnetic thin film structures can exhibit microwave oscillations that can be tunable with current as well as magnetic field. Oscillations in these structures can be due to a spin momentum transfer (SMT) effect between spin-polarized current and magnetic moments of the thin films. These structures may compose a single component oscillator with a footprint of a few hundred nanometers (nm) that are produced using thin film processes.

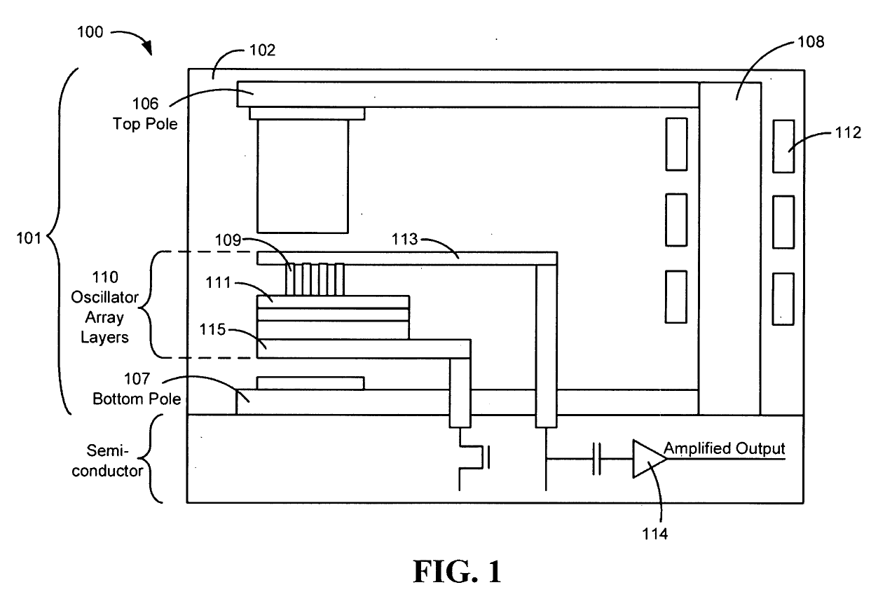

Referring to FIG. 1, a particular embodiment of a system including an oscillating device is shown and generally designated 100. The system 100 can include a magnetic thin film structure 101 that comprises the primary voltage controlled oscillator (VCO) components. The magnetic thin film structure 101 may include a magnetic top pole layer 106, a magnetic bottom pole layer 107, and a pedestal 108 disposed between the magnetic top pole layer 106 and the magnetic bottom pole layer 107. The pedestal 108 can have a coil (or solenoid) 112 wrapped around the pedestal 108. The magnetic top pole layer 106, the magnetic bottom pole layer 107, and the pedestal 108 may all comprise soft magnetic material.

In addition, the magnetic thin film structure 101 may have an oscillator array layer 110 disposed in a gap between the magnetic top pole layer 106 and the magnetic bottom pole layer 107. The oscillator array layer 110 may include nanocontact pillars 109 on spin valve layers 111. The nanocontact pillar array may be further composed of oscillator pillars and detector pillars that are electrically insulated or separated from each other. In a particular embodiment, the spin valves films are patterned much larger than corresponding nanocontact pillars to produce narrow oscillation linewidths, in the range of 2-20 MHz, at room temperature when subject to an out-of-plane approximately 0.7 T magnetic field.

There may be connections through or around the magnetic bottom pole layer 107 from the nanocontact pillars to the semiconductor device layers 104. The semiconductor 104 may include devices to regulate current to the oscillator pillars as well as other semiconductor processing components, such as an amplifier 114. The magnetic thin film structure 101 may be composed of thin film layers grown on the semiconductor 104.

During operation, current through the coil 112 can produce a magnetic field or flux in the gap between the top pole layer 106 and the bottom pole layer 107 where the oscillator array layer 110 is located. Current can then be applied to the nanocontact pillars in the oscillator array 110 to generate an oscillating giant magnetoresistive (GMR) signal between the top lead 113 and the bottom lead 115 of the oscillator array layer 110.

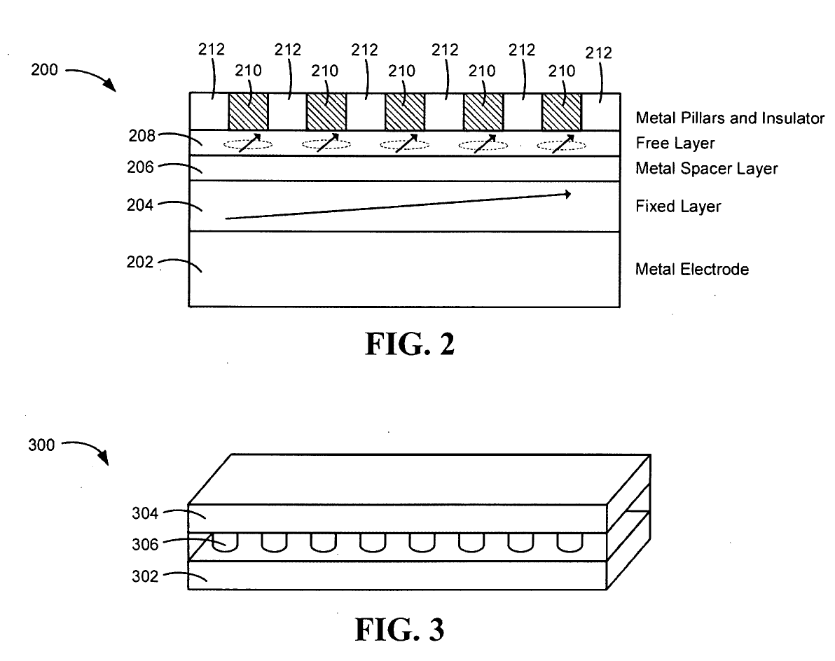

Referring to FIG. 2, a particular embodiment of an oscillating device is shown and generally designated 200. The oscillator device 200 may be the oscillator array layer 110 shown in FIG. 1. The oscillator device 200 may be constructed on an insulating layer (not shown) adjacent to a magnetic bottom pole, such as the magnetic bottom pole 110 shown in FIG. 1.

The oscillator device 200 may include a metal bottom electrode layer 202 deposited on the insulating layer. The metal electrode layer 202 may connect to a current source through the insulating layer. In addition, a fixed layer 204 may be deposited on the metal electrode layer 202. The fixed layer 204 may comprise a relatively thick soft high moment material, such as, but not limited to, Co or Co₉₀Fe₁₀ having a thickness ranging from 20 nm to 50 nm. Alternately, the fixed layer may be grown on top of an antiferromagnetic film such as PtMn or IrMn or some other antiferromagnetic material. A metal spacer layer 206 may be deposited on the fixed layer 204. The metal spacer layer 206 may be Cu with a thickness ranging from 3 nm to 5 nm.

A free layer 208 comprising a soft magnetic material with a lower moment may be deposited on the metal spacer layer 206. The free layer 208 may comprise Ni₈₀Fe₂₀ with a thickness of 1 nm to 2 nm. An array of metal pillars 210 may be grown on the free layer 208 with a specified pitch, such as 100 nm to 500 nm. The metal pillars 210 may have a diameter or width of 50 nm. The spaces between the metal pillars 210 may be filled with an insulating material 212.

The oscillator array 200 may consist of a pillar array on a spin valve film structure that is patterned to 5 μm to 10 μm on a side depending on how many oscillator elements are desired and what there spacing is. The oscillator array 200 may be rectangular, circular, or some other planar configuration.

During operation, each of the metal pillars 210, when activated by sufficient current and a magnetic field, excites sustained large angle magnetization dynamics in a portion of the free layer 208 beneath each of the metal pillars 210. Natural mutual synchronization of the dynamics beneath multiple pillars leads to a stable mono-frequency spinwave excitation throughout the free layer 208. Described herein are examples of embodiments of how the magnetic oscillations can be captured as a useful electrical oscillation signal.

Phase locking of the magnetic excitations beneath each metal pillar 210 can be achieved through a combination of nonlinear oscillator response and available mutual coupling mechanisms. Phase locking stabilizes a common frequency and phase relationship for all the oscillating metal pillars 210. The phase locking may be insensitive to details of the actual coupling mechanism and actual nonlinear response of the oscillators. The overall advantage of phase locking is a combined power that increases as N², where N is the number of oscillators, and a frequency linewidth that decreases in a range between N⁻¹ to N⁻².

Further, the oscillating pillars 210 may be slightly dissimilar and still produce a mutually phase locked system. Phase locking has been shown to occur in a system having two slightly dissimilar oscillators where the coupling is due to spinwaves traveling between the oscillators. The phase locked state may produce narrower oscillation linewidths and an enhanced power output. Yet further, coupling may also occur via an alternating current through a series connected set of SMT devices.

Referring to FIG. 3, a diagram of another illustrative embodiment of an oscillating device is shown and generally designated 300. The oscillating device 300 may include a free layer 302 and metal pillars 306 on the free layer 302, such as the free layer 208 and the metal pillars 210 shown in FIG. 2. The metal pillars 306 may all be connected via a top metal electrode 304 to form an oscillator array. The top metal electrode 304 may connect to a current supply, such as a current supply in the semiconductor 104 shown in FIG. 1.

In such an embodiment, all the metal pillars 306 may be electrically connected in parallel and current from the current supply is split to each metal pillar 306. Once activated by the current and a magnetic field, each metal pillar 306 becomes an oscillator that generates a local high amplitude spinwave disturbance in the free layer 302. Due to interaction between the spinwaves, a phase locked high amplitude spinwave mode is generated underneath the entire array of oscillators. The phase locked array of oscillators serves to stabilize the frequency of the oscillation (i.e. reduces the phase noise). An oscillating giant magnetoresistive (GMR) signal between the top metal electrode 304 and a bottom metal electrode (not shown), such as metal electrode 202 shown in FIG. 1, is generated by the spinwaves.

The electrodes of the oscillating device 300 may be capacitively coupled to a path that carries time-varying (AC) voltage due to the GMR signal to a semiconductor, such as semiconductor 104. The semiconductor 104 may include a transistor amplifier 104 connected to the path to receive and amplify the AC voltage for delivery to other circuit components.

The oscillating device 300 can serve as a voltage controlled oscillator whereby changes in the magnetic field, such as a change to current of the coil 112, or changes in the current to the oscillator array can be used to switch frequency.

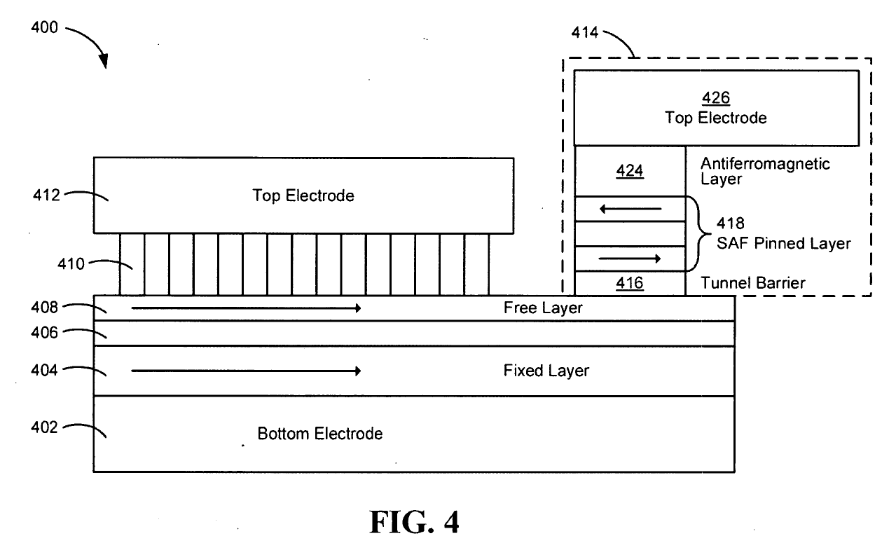

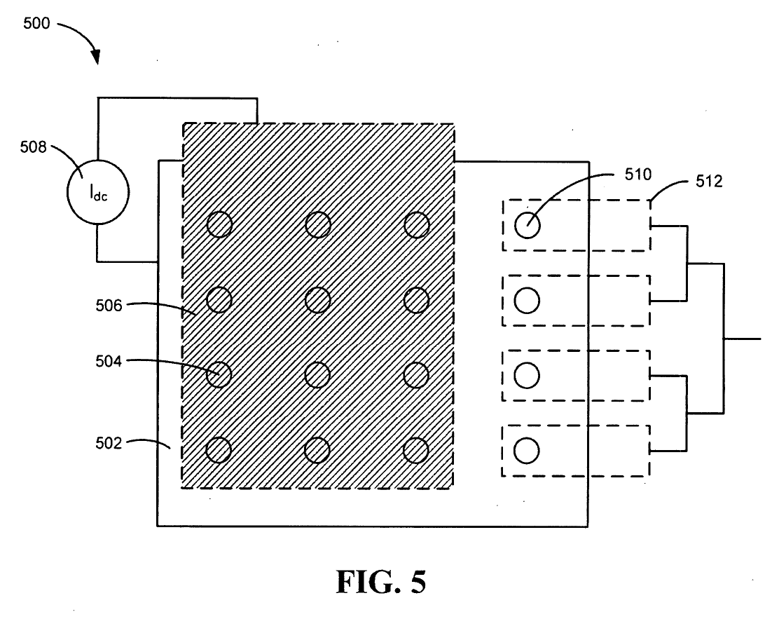

In another particular embodiment, an array of parallel connected metal pillars may be utilized but is separated and electrically insulated from other detector pillars (sensors) on the same layer. FIG. 4 and FIG. 5 illustrate embodiments of detector pillars placed outside of an oscillator array. In these embodiments, the detector pillars can be used to sense the periodic motion of the GMR signal without a high current bias requirement for the detector pillars. These embodiments allow use of high amplitude detectors such as a magnetic tunnel junction (MTJ) detector, which exhibit maximum magnetoresistance at low bias. Leads for biasing the detector pillars may be routed through or around other layers to the semiconductor. Outputs of several of the detectors may be combined to produce a higher amplitude oscillating voltage and hence a higher power output.

Referring to FIG. 4, a diagram of an illustrative embodiment of a system including an oscillating device and a detector is shown and generally designated 400. The system 400 can include a bottom electrode 402, a fixed layer 404, a spacer layer 406, and a free layer 408. The system 400 may include metal pillars 410 adjacent to the free layer 408 and a top electrode 412. Once activated by current from the top electrode 412 and a magnetic field, the metal pillars 410 can become oscillators that generate a local high amplitude spinwave disturbance in the free layer 408.

The system 400 may also include an MTJ detector 414 adjacent to the free layer 408. In a particular embodiment, the MTJ detector 414 is located on an area of the free layer 408 that is separate from an area of the free layer 408 that is adjacent the metal pillars 410. In addition, the MTJ detector 414 may be electrically isolated from the top electrode 412 and the metal pillars 410. In a particular embodiment, more than one MTJ detector may be implemented to provide additional output power.

In a particular embodiment, the MTJ detector 414 may include a tunnel barrier 416 that can be grown directly on the free layer 408. The tunnel barrier 416 may comprise AlOx, TiOx, or MgO or other appropriate barrier materials. A pinned ferromagnetic layer 418, such as a Co/Ru/Co synthetic antiferromagnetic (SAF) structure, may be deposited on the tunnel barrier 416. An antiferromagnetic film 424, such as IrMn or PtMn, may be placed on the pinned ferromagnetic layer 418. Also, there may be a top electrode 426 on the antiferromagnetic layer 424.

The MTJ detector 414 can operate as a current perpendicular to the plane (CPP) structure and can be patterned as a pillar. In a particular embodiment the pillar diameter can be in the range of 300-400 nm; however, the pillar diameter can be decreased below 100 nm. A relatively large detector device can provide increased stability of the pinned layers as well as ease of fabrication. The area surrounding the MTJ detector 414 may be filled with an insulating material.

In a particular embodiment, an expected output of the MTJ detector 414 may be determined by considering the resistance area (RA) product and the magnetoresistance ratio (MR %). In a conservative analysis, a RA=50 Ωμm² may be achieved with an MR % of approximately 50%. If the MTJ detector 414 has a 400 nm diameter, a 100 mV bias between bottom electrode 402 and top electrode 426, and a resistance change from 300Ω to 500Ω, assuming an excitation of the free layer 408 that produces half of the full magnetoresistive change, the MTJ detector 414 may produce 8.3 nW into a 50Ω load. By a coherent combining of ten MTJ detectors within an oscillating device, the overall output can be 0.83 μW. In addition, the output power can be increased when the RA is decreased and/or the MR % is increased.

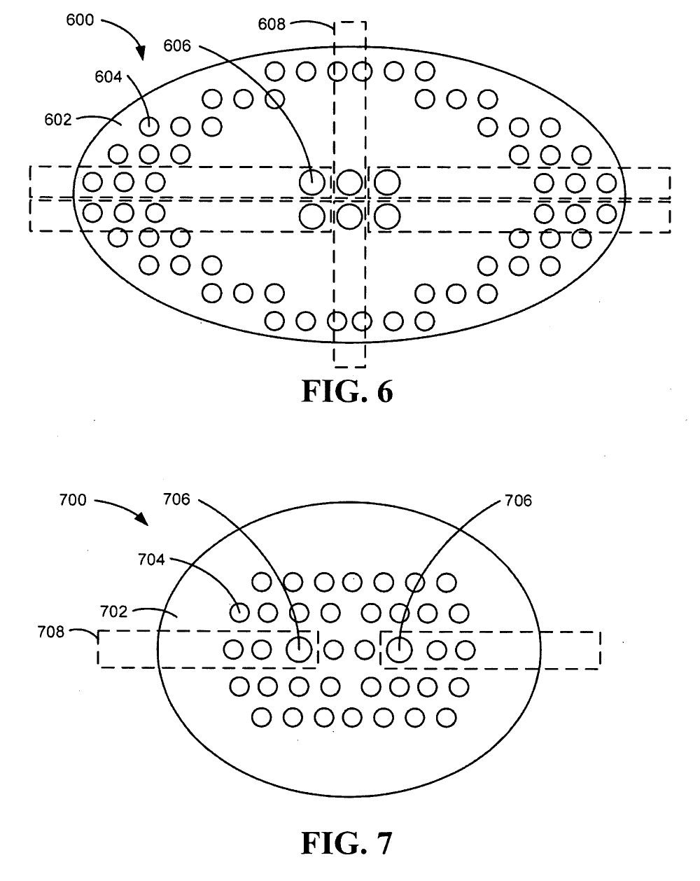

However, additional embodiments may include variations in the location of detectors, such as shown in FIG. 5, FIG. 6, and FIG. 7. Referring to FIG. 5, a diagram of an illustrative embodiment of a system including an oscillating device and a detector array is shown and generally designated 500. The system 500 may include a spin valve mesa structure 502 and metal pillars 504 adjacent the spin valve structure 502. The metal pillars 504 may be connected to an electrode 506 that provides current to the metal pillars 504 from a current source 508. When a sufficient magnetic field and current are applied to the metal pillars 504, they can become oscillators that generate a local high amplitude spinwave disturbance in the spin valve structure 502.

The system 500 may also include detector pillars 510 on the spin valve mesa structure 502 to sense the spinwave disturbance. Electrodes 512 can provide an oscillating output signal from the detector pillars 510. The detector pillars 510 may be MTJ detectors as described with respect to FIG. 4. The detector pillars 510 may be placed towards an edge of the spin valve structure 502, which may be outside of the magnetic field used to generate the spinwave disturbance. Large angle magnetic excursions of a spin valve layer can generate efficient spin wave reflection at an edge of the spin valve structure 502. The detector pillars 510 may be placed at a standing wave peak to maximize output power.

Referring to FIG. 6, a diagram of an illustrative embodiment of a system including an oscillating device and a detector array is shown and generally designated 600. The system 600 may include a spin valve mesa structure 602 and metal pillars 604 adjacent the spin valve structure 602. When a sufficient magnetic field and current are applied to the metal pillars 604, they can become oscillators that generate a local high amplitude spinwave disturbance in the spin valve structure 602. The system 600 may also include detector pillars 606 on the spin valve structure 602 to sense the spinwave disturbance. Electrodes 608 can provide an oscillating output signal from the detector pillars 606. The detector pillars 606 may be MTJ detectors as described with respect to FIG. 4.

As shown in FIG. 6, the detector pillars 606 may be placed relative to a center of the spin valve structure 602 and may be surrounded by the oscillator pillars 604. Due to symmetry, magnetic oscillations generated by the oscillator pillars 606 can cause large angle magnetization excursions at the center of the spin valve structure 602, which can result in a large amplitude oscillation output.

Referring to FIG. 7, a diagram of an illustrative embodiment of a system including an oscillating device and a detector array is shown and generally designated 700. The system 700 may include a spin valve structure 702 and metal pillars 704 adjacent the spin valve structure 702. When a sufficient magnetic field and current are applied to the metal pillars 704, they can become oscillators that generate a local high amplitude spinwave disturbance in the spin valve structure 702. The system 700 may also include detector pillars 706 on the spin valve structure 702 to sense the spinwave disturbance. Electrodes 708 can provide an oscillating output signal from the detector pillars 706. The detector pillars 706 may be MTJ detectors as described with respect to FIG. 4.

As shown in FIG. 7, the detector pillars 706 may be placed within the array of oscillator pillars 704 where large angle magnetization excursions of the free layer are expected to occur. Access to the detector pillars 706 by the electrodes 708 may be made through a top electrode (not shown) for biasing the oscillator pillars 704.

Optimum locations for detectors may correspond to points of maximum magnetization excursion for the particular spin wave excited. This may depend on numerous factors such as the shape of the spin valve structure, the quality of an edge of the spin valve structure, and the configuration of the oscillator pillars, as well as other possible factors. Determination of the optimum location for placing the detectors may be determined by detailed micromagnetic modeling.

The designs discussed herein contemplate a stand-alone oscillator device that may also be integrated with other components on a chip, such as for system-on-a-chip applications. Such application may include wireless transceivers. Transceivers utilizing these designs may benefit from extra space on the chip for other applications, such as on-board memory, due to the small footprint of the described magnetic VCOs. In a particular embodiment, the VCO designs discussed herein can utilize a 20 μm² footprint.

In another embodiment, a magnetic VCO as described herein could be used as a microwave current source for a magnetic write head to enable microwave-assisted magnetic recording. The magnetic VCO could be bonded to a slider or could be fabricated within the thin film process of the read-write head itself. Microwave current from the write head could apply a microwave magnetic field to the recording media. When the microwave current is sufficiently tuned to the resonance frequency of magnetic grains in the recording media, then the switching field for the magnetic grains may be reduced.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Moreover, although specific embodiments have been illustrated and described herein, it should be appreciated that any subsequent arrangement designed to achieve the same or similar purpose may be substituted for the specific embodiments shown.

This disclosure is intended to cover any and all subsequent adaptations or variations of various embodiments. Combinations of the above embodiments, and other embodiments not specifically described herein, will be apparent to those of skill in the art upon reviewing the description. Additionally, the illustrations are merely representational and may not be drawn to scale. Certain proportions within the illustrations may be exaggerated, while other proportions may be reduced. Accordingly, the disclosure and the figures are to be regarded as illustrative and not restrictive.

What is claimed is:

1. A device comprising:
a thin film structure comprising:
a magnetic top pole layer;
a magnetic bottom pole layer not in direct contact with the magnetic top pole layer;
a pedestal connecting the top pole layer and the bottom pole layer;
a coil wrapped around the pedestal to produce a magnetic flux in a space between the magnetic top pole layer and the magnetic bottom pole layer when current is applied to the coil;
an oscillator array structure disposed between the magnetic top pole layer and the magnetic bottom pole layer, the oscillator array structure comprising:
spin valve layers;
a first array of metal pillars adjacent the spin valve layers; and
an output path coupled to the first array of metal pillars;
wherein each of the metal pillars comprises an oscillator that produces a phase-locked spinwave disturbance in a spin valve free layer when current is applied to the first array of metal pillars and magnetic flux is applied to the oscillator array structure.

2. The device of claim 1 wherein the oscillator array layer further comprises:
an insulating layer adjacent the magnetic bottom pole layer;
a metal bottom electrode layer adjacent the insulating layer and having a connection to a current source;
the spin valve layers adjacent the metal bottom layer;
a spin valve composed of fixed and free magnetic layers, the free layer comprising a soft magnetic material;
a first array of metal pillars adjacent the spin valve layers;
an insulator layer within a space between pillars of the array of metal pillars;
a top metallic electrode layer electrically coupling the first array of metal pillars to a current source; and
the output path coupled to the top metallic electrode layer.

3. The device of claim 1 further comprising a current source to supply current to the first array of metal pillars.

4. The device of claim 1 further comprising:
a semiconductor structure having an input coupled to the output path to receive the output signal from the thin film structure.

5. The device of claim 4 wherein the semiconductor structure further comprises:
an amplifier to provide an amplified output signal based on the output signal from the thin film structure; and
an output path to provide the amplified output signal.

6. The device of claim 4 wherein the oscillator array structure further comprises:
a second array of metal pillars on the same layer as the first array of metal pillars, the second array of metal pillars and the first array of metal pillars are electrically insulated from each other, the second array of metal pillars comprising detectors that sense periodic motion of the magnetization of the spin valve layer;
an electrical connection from the semiconductor structure to the second array of metal pillars to allow biasing of the second array of metal pillars;
wherein the semiconductor structure further comprises a device coupled to the electrical connection to bias the second array of metal pillars; and
wherein an output of at least several of the detectors are combined to produce an oscillating voltage as the output signal when current is applied to the first array of pillars.

7. The device of claim 6 wherein the detectors comprise magnetic tunnel junctions (MTJs), wherein an MTJ free layer is the same as the spin valve free layer, and the insulating barrier of the MTJ is adjacent to the spin valve free layer.

8. The device of claim 6 wherein at least two of the oscillators comprise phase-locked spin momentum transfer oscillators.

9. The device of claim 1 wherein each pillar in the first array of metal pillars is electrically connected in parallel.

10. The device of claim 1 wherein the detector is generally cylindrical in shape.

11. A thin film device comprising:
a magnetic field generating component;
an oscillator array structure disposed with the magnetic field, the oscillator array layer comprising:
spin valve layers;
an array of oscillators positioned adjacent the spin valve layers that produce a phase locked, spinwave disturbance throughout the spin valve free layer when current is applied to the first array of oscillators;
an array of detectors that sense periodic motion of the magnetization of the spin valve layer; and
an output coupled to the array of detectors.

12. The thin film device of claim 11 wherein the array of oscillators comprise a first array of metal pillars in a first thin film layer and the array of detectors comprises a second array of metal pillars in the first thin film layer, wherein the first array of metal pillars and the second array of metal pillars are electrically separated.

13. The thin film device of claim 12 wherein the first thin film layer comprises a first portion within the magnetic field and a second portion not within the magnetic field, and the oscillator array is located in the first portion and the detector array is located in the second portion.

14. The thin film device of claim 12 wherein the thin film spin valve layers comprise a middle portion and an outer portion surrounding the middle portion, and the first oscillator array is located in the outer portion and the detector array is located in the middle portion.

15. The thin film device of claim 12 wherein the oscillators are interposed between the detectors within the first thin film layer.

16. The thin film device of claim 11 wherein the magnetic field generating component comprises:
a magnetic top pole layer;
a magnetic bottom pole layer not in direct contact with the magnetic top pole layer;
a pedestal connecting the top pole layer and the bottom pole layer; and
a coil wrapped around the pedestal to produce a magnetic flux in a space between the magnetic top pole layer and the magnetic bottom pole layer when current is applied to the coil.

17. The thin film device of claim 11 wherein the output further comprises an oscillating voltage combined from an output of at least several of the detectors.

18. A device comprising:
a magnetic thin film structure that provides a magnetic field;
an oscillator array structure within the magnetic thin film structure, the oscillator array structure comprising:
spin valve layers;
an array of oscillators positioned adjacent the spin valve free layer that produce a phase-locked spinwave disturbance in the spin valve free layer when current is applied to the first array of oscillators;
an array of detectors that sense periodic motion of the magnetization of the spin valve free layer and produce an oscillating output;
a semiconductor layer coupled to the magnetic thin film head structure, the semiconductor layer comprising:
a current supply coupled to the oscillators to regulate current to the oscillators;
an input coupled to the oscillating output; and
an interconnect to provide an output to other devices.

19. The device of claim 18 wherein the semiconductor layer further comprises an amplifier coupled to the input and the output to provide an amplified oscillating output coupled to the interconnect.

20. The device of claim 18 wherein the oscillating output current is used to create an oscillating assist magnetic field for the purpose of microwave assist magnetic recording.

21. The device of claim 19 further comprising:
the magnetic thin film structure further comprises:
a top pole layer;
a bottom pole layer not in direct contact with the top pole layer;
a pedestal disposed between the top pole layer and the bottom pole layer; and
a coil wrapped around the pedestal to produce a magnetic flux in a space between the top pole layer and the bottom pole layer when current is applied to the coil;
wherein the top pole layer, the bottom pole layer, and the pedestal comprise a soft magnetic film material;
the oscillator array structure further comprises:
an insulating layer adjacent the bottom pole layer;
a metal bottom electrode layer adjacent the insulating layer and having a connection for a current source;
the spin valve layers adjacent the metal bottom layer, the spin valve layer comprising soft magnetic materials;
the array of oscillators and the array of detectors are electrically separated within a thin film layer adjacent the spin valve layer;
an insulator layer within spaces between pillars of the array of oscillators and pillars of the array of detectors;
a top metallic electrode layer electrically coupling the array of oscillators to the current supply of the semiconductor layer; and
an output path coupled to the array of detectors to provide the oscillating output to the semiconductor layer;
the array of oscillators comprises a phase locked array of oscillators;
the array of detectors comprises an array of magnetic tunnel junction detectors; and
the oscillating output further comprises an oscillating voltage combined from an output of at least several of the detectors.
